(19) United States
(12) Patent Application Publication
(10) Pub. No.: US 2005/0258137 A1
(43) Pub. Date: Nov. 24, 2005

(54) Remote chamber methods for removing surface deposits

(76) Inventors: Herbert H. Sawin, Chestnut Hill, MA (US); Bo Bai, Cambridge, MA (US)

Correspondence Address: E I DU PONT DE NEMOURS AND COMPANY;LEGAL PATENT RECORDS CENTER, BARLEY MILL PLAZA 25/1128, 4417 LANCASTER PIKE, WILMINGTON, DE, 19805, US

(21) Appl. No.: 11/087,788

(22) Filed: Mar. 23, 2005

Related U.S. Application Data
(60) Provisional application No. 60/556,227, filed on Mar. 24, 2004.

(51) Int. Cl. H01L 21/302; B44C 1/22

(52) U.S. Cl. 216/58; 216/74; 438/905; 216/69

(57) ABSTRACT

The present invention relates to an improved remote plasma cleaning method for removing surface deposits from a surface, such as the interior of a deposition chamber that is used in fabricating electronic devices. The improvement involves using an activated gas with high neutral temperature of at least about 3,000 K. The improvement also involves optimizing oxygen to fluorocarbon ratios for better etching rates and emission gas control.

### BACKGROUND OF THE INVENTION

1. Field of the Invention

The present invention relates to methods for removing surface deposits by using an activated gas created by remotely activating a gas mixture comprising of oxygen and fluorocarbon. More specifically, the present invention relates to methods for removing surface deposits from the interior of a chemical vapor deposition chamber using an activated gas created by remotely activating a gas mixture comprising of oxygen and perfluorocarbon.

2. Description of Related Art

Remote plasma sources for the production of atomic fluorine are widely used for chamber cleaning in the semiconductor processing industry, particularly in the cleaning of chambers used for Chemical Vapor Deposition (CVD) and Plasma Enhanced Chemical Vapor Deposition (PECVD). The use of remote plasma sources avoids some of the erosion of the interior chamber materials that occurs with in situ chamber cleans in which the cleaning is performed by creating a plasma discharge within the PECVD chamber. While capacitively and inductively coupled RF as well as microwave remote sources have been developed for these sorts of applications, the industry is rapidly moving toward transformer coupled inductively coupled sources in which the plasma has a torroidal configuration and acts as the secondary of the transformer. The use of lower frequency RF power allows the use of magnetic cores which enhance the inductive coupling with respect to capacitive coupling; thereby allowing the more efficient transfer of energy to the plasma without excessive ion bombardment which limits the lifetime of the remote plasma source chamber interior.

The semiconductor industry has shifted away from mixtures of fluorocarbons with oxygen for chamber cleaning, which initially were the dominant gases used for in situ chamber cleaning for a number of reasons. First, the emissions of global warming gases from such processes was commonly much higher than that of nitrogen trifluoride (NF₃) processes. NF₃ dissociates more easily in a discharge and is not significantly formed by recombination of the product species. Therefore, low levels of global warming emissions can be achieved more easily. In contrast, fluorocarbons are more difficult to breakdown in a discharge and recombine to form species such as tetrafluoromethane (CF₄) which are even more difficult to break down than other fluorocarbons.

Secondly, it was commonly found that fluorocarbon discharges produced “polymer” depositions that require more frequent wet cleans to remove these deposits that build up after repetitive dry cleans. The propensity of fluorocarbon cleans to deposit “polymers” occurs to a greater extent in remote cleans in which no ion bombardment occurs during the cleaning. These observations dissuaded the industry from developing industrial processes based on fluorocarbon feed gases. In fact, the PECVD equipment manufacturers tested remote cleans based on fluorocarbon discharges, but to date have been unsuccessful because of polymer deposition in the process chambers.

However, if the two drawbacks as described above can be resolved, fluorocarbon gases are desirable for their low cost and low-toxicity.

### BRIEF SUMMARY OF THE INVENTION

The present invention relates to a method for removing surface deposits, said method comprising: (a) activating in a remote chamber a gas mixture comprising oxygen and fluorocarbon, wherein the molar ratio of oxygen and fluorocarbon is at least 1:4, using sufficient power for a sufficient time such that said gas mixture reaches a neutral temperature of at least about 3,000 K to form an activated gas mixture; and thereafter (b) contacting said activated gas mixture with the surface deposits and thereby removing at least some of said surface deposits.

### BRIEF DESCRIPTION OF THE DRAWING(S)

FIG. 1. Schematic diagram of an apparatus useful for carrying out the present process.

FIG. 2. Plot of etch rate of silicon dioxide at 100° C. as a function of O₂ percentage in perfluorocarbon and O₂ mixture.

FIG. 3. Plots of Fourier Transformed Infrared Spectroscopy (FTIR) measurements of the concentration of emission gases from the pump of (a) NF₃+Ar, (b) C₃F₈+O₂+Ar, (c) C₄F₈+O₂+Ar, and (d) CF₄+O₂+Ar discharges.

FIG. 4. Bar charts of FTIR measurements of the concentration of emission gases from the pump of C₄F₈ discharges with (a) different C₄F₈ flow rates, and (b) different O₂ percentages.

FIG. 5. X-ray photoelectron spectroscopy (XPS) measurements on flat sapphire wafer surface exposed to C₂F₆ activated gases (a) with and (b) without O₂ addition.

FIG. 6. Comparison of atomic force microscope (AFM) micrographs of sapphire wafer surfaces (a) before exposed to C₂F₆ activated gas, and after exposed to C₂F₆ activated gases (b) with and (c) without O₂ addition.

### DETAILED DESCRIPTION OF THE INVENTION

Surface deposits removed in this invention comprise those materials commonly deposited by chemical vapor deposition or plasma-enhanced chemical vapor deposition or similar processes. Such materials include silicon, doped silicon, silicon nitride, tungsten, silicon dioxide, silicon oxynitride, silicon carbide and various silicon oxygen compounds referred to as low K materials, such as FSG (fluorosilicate glass) and SiCOH or PECVD OSG including Black Diamond (Applied Materials), Coral (Novellus Systems) and Aurora (ASM International).

One embodiment of this invention is removing surface deposits from the interior of a process chamber that is used in fabricating electronic devices. Such process chamber could be a Chemical Vapor Deposition (CVD) chamber or a Plasma Enhanced Chemical Vapor Deposition (PECVD) chamber.

The process of the present invention involves an activating step using sufficient power to form an activated gas mixture having neutral temperature of at least about 3,000 K. Activation may be accomplished by any means allowing for the achievement of dissociation of a large fraction of the feed gas, such as: RF energy, DC energy, laser illumination and microwave energy. The neutral temperature of the resulting plasma depends on the power and the residence time of the gas mixture in the remote chamber. Under certain power input and conditions, neutral temperature will be higher with longer residence time. Here, preferred neutral temperature is over about 3,000 K. Under appropriate conditions (considering power, gas composition, gas pressure and gas residence time), neutral temperatures of at least about 6000 K may be achieved, for example, with octafluorocyclobutane.

The activated gas is formed in a remote chamber that is outside of the process chamber, but in close proximity to the process chamber. The remote chamber is connected to the process chamber by any means allowing for transfer of the activated gas from the remote chamber to the process chamber. The remote chamber and means for connecting the remote chamber with the process chamber are constructed of materials known in this field to be capable of containing activated gas mixtures. For instance, aluminum and stainless steel are commonly used for the chamber components. Sometimes Al₂O₃ is coated on the interior surface to reduce the surface recombination.

The gas mixture that is activated to form the activated gas comprises oxygen and fluorocarbon. A fluorocarbon of the invention is herein referred to as a compound comprising of C and F. Preferred fluorocarbon in this invention is perfluorocarbon compound. A perfluorocarbon compound in this invention is herein referred to as a compound consisting of C, F and optionally oxygen. Such perfluorocarbon compounds include, but are not limited to tetrafluoromethane, hexafluoroethane, octafluoropropane, hexafluorocyclopropane decafluorobutane, octafluorocyclobutane, carbonyl fluoride and octafluorotetrahydrofuran. Preferred of the perfluorocarbons is octafluorocyclobutane.

The gas mixture that is activated to form the activated gas may further comprise a carrier gas such as nitrogen, argon and helium.

The total pressure in the remote chamber during the activating step may be between about 0.5 Torr and about 20 Torr.

The gas mixture comprises oxygen and fluorocarbon in a molar ratio of at least about 1:4. Under the high neutral temperature condition used in this invention, oxygen in excess of 10 molar percent of the stoichiometric requirement (i.e., the amount of oxygen necessary to convert all carbon in the fluorocarbon to CO₂) results in surprisingly good deposition chamber cleaning rates, eliminates fluorocarbon emissions except COF₂ and prevents fluorocarbon polymer depositions on the deposition surfaces.

The gas mixture is activated using sufficient power for a sufficient time such that said gas mixture reaches a neutral temperature of at least about 3,000 K to form an activated gas mixture. For example, a power range of from about 3,000-15,000 watts in a 0.25 liter remote chamber corresponds to a power density of from about 12,000-60,000 watts/liter. These values scale both up and down for remote chambers of different sizes. The residence time of the gas mixture in the remote chamber under such power input must be sufficient such that the gas mixture achieves a neutral temperature of at least about 3,000K. For appropriate conditions (considering power, gas composition, gas pressure and gas residence time), neutral temperatures of at least about 6000K may be achieved, for example, with octafluorocyclobutane. A preferred embodiment of the present invention is a method for removing surface deposits from the interior of a process chamber that is used in fabricating electronic devices, said method comprising: (a) activating in a remote chamber a gas mixture comprising oxygen and perfluorocyclobutane in a mole ratio of at least from about 2:1 to about 20:1 using power of at least from about 3,000 watts for a sufficient time such that said gas mixture reaches a neutral temperature of at least about 3,000 K to form an activated gas mixture; and thereafter (b) contacting said activated gas mixture with the interior of said deposition chamber and thereby removing at least some of said surface deposits.

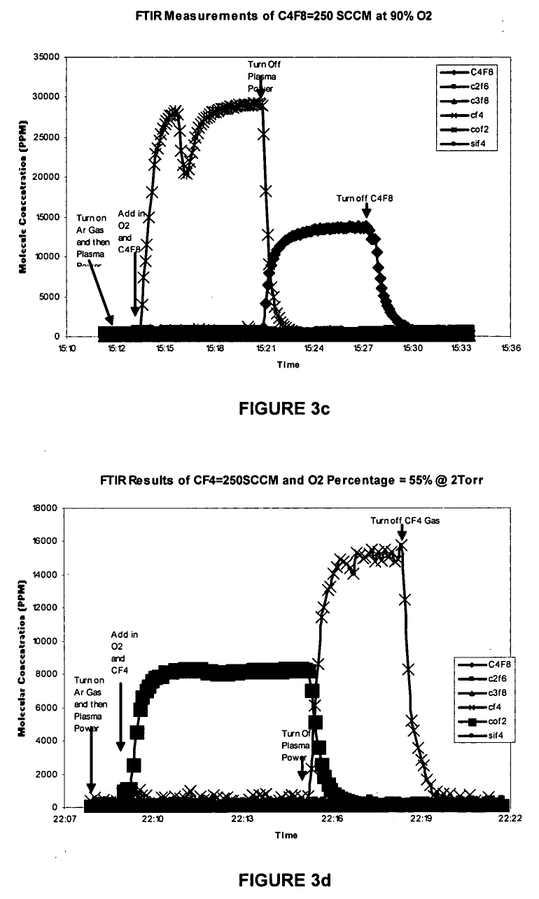

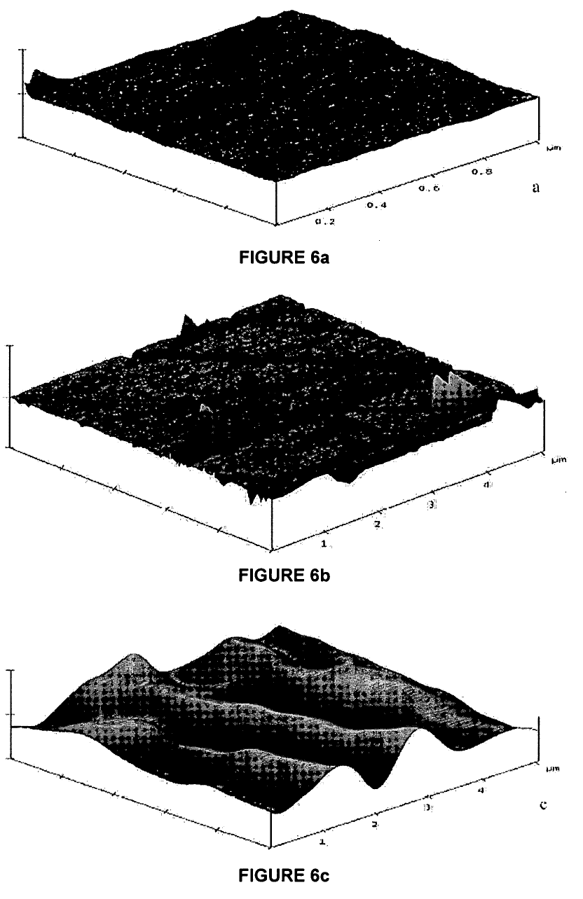

It was also found that at the similar conditions of this invention, the drawbacks of the perfluorocarbon compound, i.e. global warming gases emission and polymer deposition, can be overcome. In the experiments of this invention, no significant polymer depositions on the interior surface of chamber was found. See also FIGS. 6a, b and c. The global warming gas emissions were also very low as shown in FIGS. 3a, b, c and d.

Alternatively, the system can be used to alter surfaces placed in the remote chamber by contact with the fluorine atoms and other constituents coming from the source.

The following Examples are meant to illustrate the invention and are not meant to be limiting.

### EXAMPLES

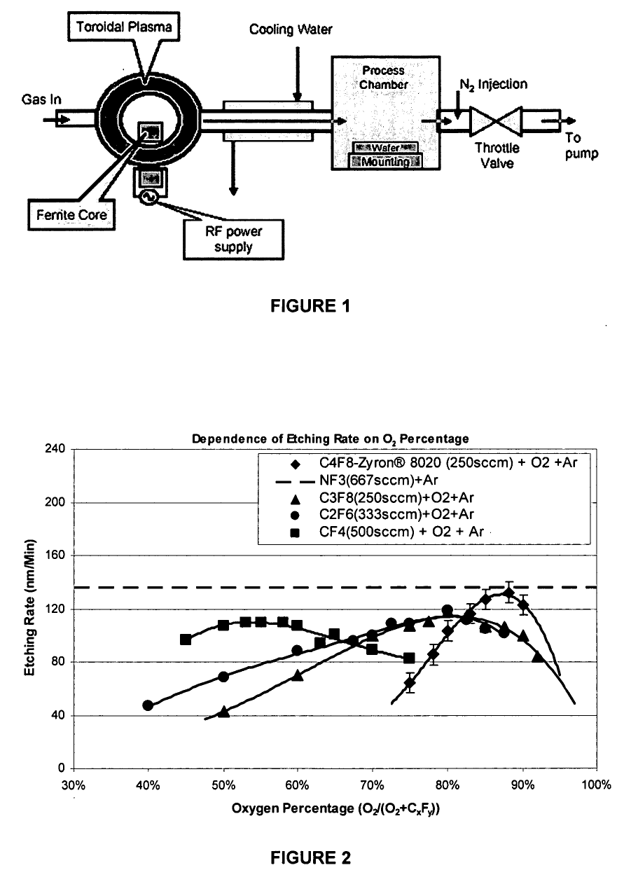

FIG. 1 shows a schematic diagram of the remote plasma source and apparatus used to measure the etching rates, plasma neutral temperatures, and exhaust emissions. The remote plasma source is a commercial toroidal-type MKS ASTRON®ex reactive gas generator unit made by MKS Instruments, Andover, Mass., USA. The feed gases (e.g. oxygen, fluorocarbon, Argon) were introduced into the remote plasma source from the left, and passed through the toroidal discharge where they were discharged by the 400 KHz radio-frequency power to form an activated gas mixture. The oxygen is manufactured by Airgas with 99.999% purity. The fluorocarbon is Zyron® 8020 manufactured by DuPont with minimum 99.9 vol % of octafluorocyclobutane. Argon is manufactured by Airgas with grade of 5.0. The activated gas then passed through an aluminum water-cooled heat exchanger to reduce the thermal loading of the aluminum process chamber. The surface deposits covered wafer was placed on a temperature controlled mounting in the process chamber. The neutral temperature is measured by Optical Emission Spectroscopy (OES), in which rovibrational transition bands of diatomic species like C₂ and N₂ are theoretically fitted to yield neutral temperature. See also B. Bai and H. Sawin, Journal of Vacuum Science & Technology A 22 (5), 2014 (2004), herein incorporated as a reference. The etching rate of the surface deposits by the activated gas is measured by interferometry equipment in the process chamber. N₂ gas is added at the entrance of the pump both to dilute the products to a proper concentration for FTIR measurement and to reduce the hang-up of products in the pump. FTIR was used to measure the concentration of species in the pump exhaust.

### EXAMPLE 1

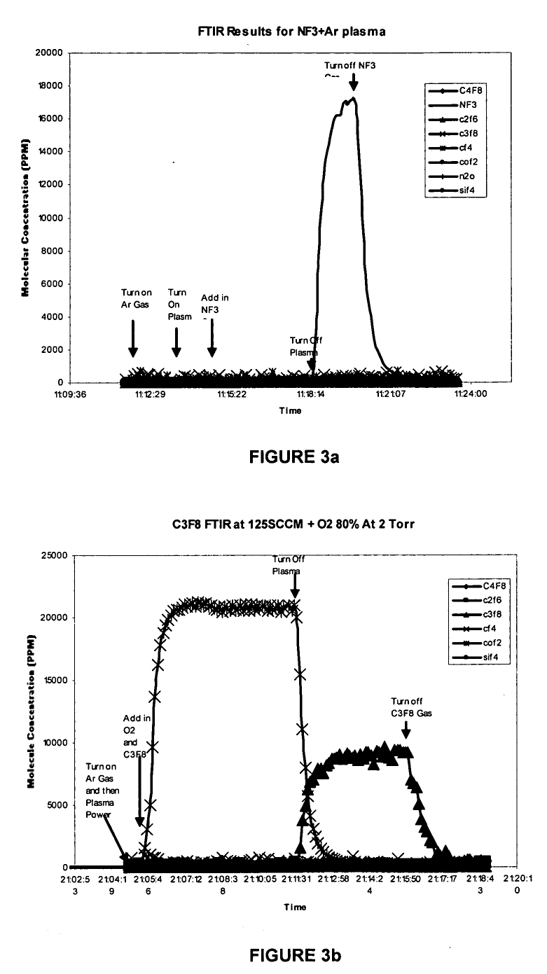

The feeding gas composed of O₂, perfluorocarbon and Ar, wherein the perfluorocarbon is Zyron® 8020 (C₄F₈), C₃F₈, C₂F₆, or CF₄. The flow rates of perfluorocarbons in this Example were adjusted so that the molar flow rate of elemental fluorine into the remote chamber was the same for all mixtures. In this Example, the flow rates for C₄F₈, C₃F₈, C₂F₆, and CF₄ were 250, 250, 333 and 500 sccm respectively, which are all equivalent to 2000 sccm of elemental fluorine. The percentage flow rate of O₂ to the total of O₂ and perfluorocarbon was changed to detect the etching rate dependence on the O₂ percentage. See FIG. 2. The total feeding gas flow rate was fixed at 4000 sccm by adjusting argon flow. Nitrogen was added between the process chamber and the pump at a flow rate of 20,000 sccm. Chamber pressure is 2 torr. The feeding gas was activated by 400 KHz RF power to a neutral temperature of more than 5000 K. The activated gas then entered the process chamber and etched the SiO₂ surface deposits on the mounting with the temperature controlled at 100° C. The results are showed in FIG. 2.

As a reference, the etching rate of NF₃+Ar plasma is shown in FIG. 2 since it is the standard gas used for remote chamber cleaning. All the conditions for NF₃ were the same as described above for perfluorocarbons except the NF₃ flow rate was 667 sccm which is equivalent to 2000 sccm of elemental fluorine. As shown in FIG. 2, the percentage of O₂ (O₂/(CₓF_{y}+O₂)) is critical to the etching rates of perfluorocarbons. The optimum O₂ percentage allows perfluorocarbon etching rates to be close to the NF₃ etching rate.

The O₂ percentages corresponding to the maximum etching rates for CF₄, C₂F₆, C₃F₈ and C₄F₈ were 55%, 77%, 80% and 87% respectively. The optimum O₂ percentages are different from that of in situ chamber cleaning with perfluorocarbon gases or with remote microwave sources. These are also beyond the expected stoichiometric amount of oxygen required to convert all carbons in the fluorocarbon to CO₂.

### EXAMPLE 2

The common experimental conditions for FIGS. 3a, 3b, 3c and 3d are described in the following paragraph below.

Chamber pressure was 2 torr. The feeding gas was activated by 400 KHz RF power to a neutral temperature of more than 3000 K for NF₃ gas mixture and more than 5000K for perfluorocarbon gas mixtures. The activated gas then entered the process chamber and etched the SiO₂ surface deposits on the mounting with the temperature controlled at 100° C. FTIR was used to measure the concentration of emission species in the pump exhaust.

As for FIG. 3a, the feeding gas composed of NF₃ and Argon with flow rates of 333 sccm and 3667 sccm respectively.

As for FIG. 3b, the feeding gas composed of 125 sccm of C₃F₈, 500 sccm of O₂ and 3375 sccm of Argon.

As for FIG. 3c, the feeding gas composed of 125 sccm of C₄F₈, 1125 sccm of O₂ and 2750 sccm of Argon.

As for FIG. 3d, the feeding gas composed of 250 sccm of CF₄, 306 sccm of O₂ and 3444 sccm of Argon.

FIGS. 3a, 3b, 3c, and 3d show the concentration of emission species in the pump exhaust as measured by FTIR. FIG. 3a show that NF₃ was nearly completely decomposed by the ASTRON®ex plasma. Similarly, C₃F₈, CF₄, and C₄F₈ were nearly completely destroyed at their respective optimum oxygen mixtures with no measurable perfluorocarbons observed in the pump exhaust. However, large amounts of COF₂ were present in the pump discharge.

Result from C₂F₆ was similar and not shown here. Obviously under current inventive conditions, there is no perfluorocarbon emission except COF₂ for perfluorocarbon containing mixture discharges. This is quite different from results of in situ chamber cleaning with perfluorocarbon gases where the perfluorocarbon emissions are significant.

### EXAMPLE 3

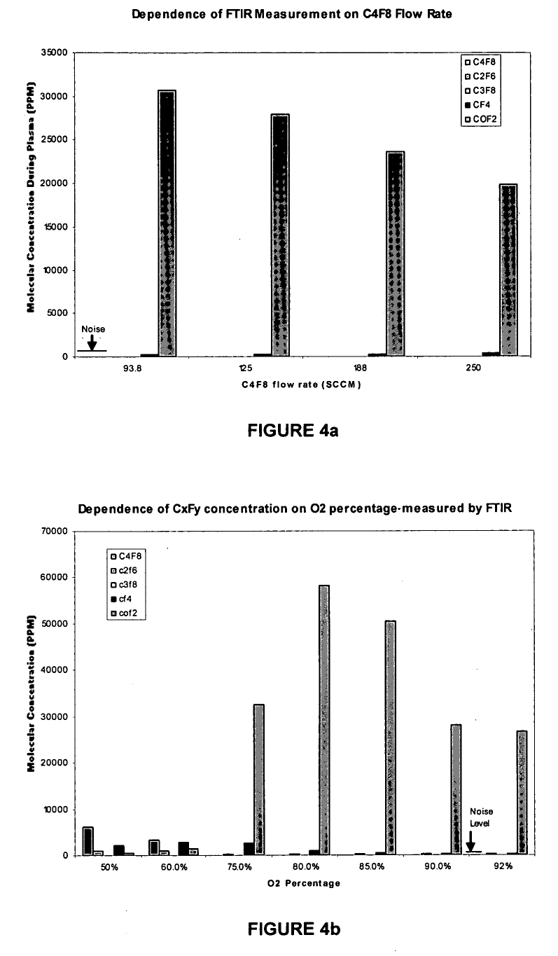

FIGS. 4a and 4b demonstrate the effects of perfluorocarbon flow rate and O₂ percentage (O₂/(CₓF_{y}+O₂)) on the concentration of emission gases. For both Figures, from left to right the bars in each group indicate emission concentrations of C₄F₈, C₂F₆, C₃F₈, CF₄ and COF₂. For the experiments of FIG. 4a, the C₄F₈ flow rates was 93.75 sccm, 125 sccm, 187.5 sccm or 250 sccm, as shown at axis X of the Figure. The corresponding O₂ flow rates are 656, 875, 1313 and 1750 sccm, respectively. The total feeding gas flow rate was fixed at 4000 sccm by adjusting Argon flow. Chamber pressure was 2 torr. The feeding gas was activated by 400 KHz RF power to a neutral temperature of more than 5000 K. The activated gas then entered the process chamber and etched the SiO₂ surface deposits on the mounting with the temperature controlled at 100° C. FTIR was used to measure the concentration of emission species in the pump exhaust.

For the experiments of FIG. 4b, the C₄F₈ flow rates was 250 sccm. The O₂ flow rate was 250, 375, 750, 1000, 1417, 2250 and 2875 sccm, indicated as O₂ percentage at axis X of the Figure. The total feeding gas flow rate was fixed at 4000 sccm by adjusting Argon flow. Chamber pressure was 2 torr. The feeding gas was activated by 400 KHz RF power to a neutral temperature of more than 5000 K. The activated gas then entered the process chamber and etched the SiO₂ surface deposits on the mounting with the temperature controlled at 100° C. FTIR was used to measure the concentration of emission species in the pump exhaust.

In FIG. 4a the perfluorocarbon emission was measured when C₄F₈ flow rate was varied while O₂ percentage was kept at the optimum condition. No measurable perfluorocarbon emission was detected.

FIG. 4b demonstrates that when O₂ percentages were close to or higher than the optimum value, no measurable perfluorocarbon emission was detected under the current inventive conditions. However, when O₂ percentages were much lower than the optimum value, perfluorocarbon emissions began to appear. These results suggest that the amount of O₂ added in perfluorocarbon plasma is critical to complete dissociation of perfluorocarbon gases and the reduction of perfluorocarbon emissions.

### EXAMPLE 4

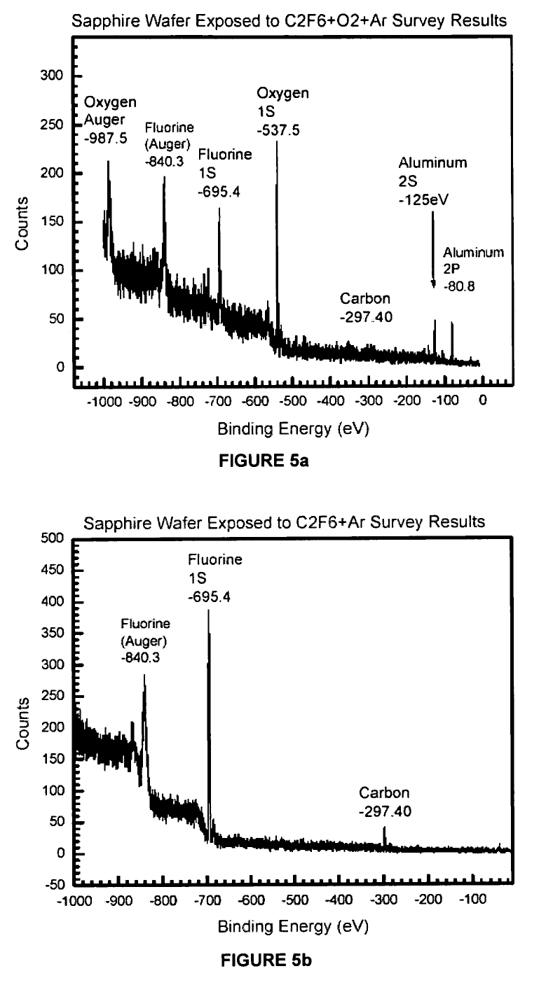

In this experiment, the surface composition of a sapphire sample was measured before and after exposed to the activated gases in the process chamber. FIGS. 5a and 5b are the X-ray Photoelectron Spectroscopy (XPS) of the sapphire surfaces. FIGS. 6a, 6b, and 6c are Atomic Force Microscope (AFM) measurements of sapphire surfaces.

For experiments of FIGS. 5a and 6b, the feeding gas composed of 2233 sccm of O₂, 667 sccm of C₂F₆ and 1100 sccm of Ar. Chamber pressure is 2 torr. The feeding gas was activated by 400 KHz RF power to a neutral temperature of more than 5000 K. The activated gas then entered the process chamber with the sapphire sample on the mounting with the temperature controlled at 25° C.

For experiments of FIGS. 5b and 6c, the feeding gas composed of 667 sccm of C₂F₆ and 1100 sccm of Ar. Other conditions were the same as those described above for experiments of FIGS. 5a and 6b.

FIG. 5a was the measurement of the sapphire surface after a 10 minute exposure to the activated gas. Signal of oxygen, aluminum and fluorine were present on the surface, however no carbon was observed. Similar results were observed for C₄F₈ and CF₄ discharges. This suggests that with optimized O₂ percentage, perfluorocarbon gases can be used for chamber cleaning without any perfluorocarbon deposition. The AFM measurements confirmed this conclusion. FIG. 6a was the measurement of the sapphire surface before exposure and FIG. 6b was the measurement of the sapphire surface after a 10 minute exposure. FIGS. 6a and 6b show no measurable changes, indicating no significant perfluorocarbon polymer deposition on the sapphire surface.

FIG. 5b was the measurement of the sapphire surface after a 10 minute exposure to the oxygen-free activated gas. With no O₂ in the feeding gas, only signals of carbon and fluorine were observed in FIG. 5b, indicating a deposition of a perfluorocarbon polymer film that covered the sapphire sufficiently that the substrate could not be seen. This result was confirmed by AFM measurement of FIG. 6c where the smooth surface suggested the deposition of a perfluorocarbon polymer film on the surface.

1. A method for removing surface deposits, said method comprising:
(a) activating in a remote chamber a gas mixture comprising oxygen and fluorocarbon, wherein the molar ratio of oxygen and fluorocarbon is at least 1:4, using sufficient power for a sufficient time such that said gas mixture reaches a neutral temperature of at least about 3,000 K to form an activated gas mixture; and thereafter
(b) contacting said activated gas mixture with the surface deposits and thereby removing at least some of said surface deposits.

2. The method of claim 1 wherein said surface deposits is removed from the interior of a deposition chamber that is used in fabricating electronic devices.

3. The method of claim 1 wherein said power is generated by an RF source, a DC source or a microwave source.

4. The method of claim 1 wherein said fluorocarbon is a perfluorocarbon compound.

5. The method of claim 4 wherein said perfluorocarbon is selected from the group consisting of tetrafluoromethane, hexafluoroethane, octafluoropropane, octafluorocyclobutane, carbonyl fluoride, perfluorotetrahydrofuran.

6. The method of claim 1 wherein said gas mixture further comprises a carrier gas.

7. The method of claim 6 wherein said carrier gas is at least one gas selected from the group of gases consisting of nitrogen, argon and helium.

8. The method of claim 1, wherein the pressure in the remote chamber is between 0.5 Torr and 20 Torr.

9. The method of claim 1, wherein the surface deposit is selected from a group consisting of silicon, doped silicon, silicon nitride, tungsten, silicon dioxide, silicon oxynitride, silicon carbide and various silicon oxygen compounds referred to as low K materials.

10. The method of claim 1, wherein the molar ratio of oxygen and fluorocarbon is at least from about 2:1 to about 20:1.

11. A method for removing surface deposits from the interior of a deposition chamber that is used in fabricating electronic devices, said method comprising:
(a) activating in a remote chamber a gas mixture comprising oxygen and perfluorocyclobutane in a mole ratio of at least from about 2:1 to about 20:1 using power of at least from about 3,000 watts for a sufficient time such that said gas mixture reaches a neutral temperature of at least about 3,000 K to form an activated gas mixture; and thereafter
(b) contacting said activated gas mixture with the interior of said deposition chamber and thereby removing at least some of said surface deposits.
